(19) United States
(12) Patent Application Publication
(10) Pub. No.: US 2008/0122945 A1
(43) Pub. Date: May 29, 2008

(54) Shutter key for mobile electronic device with image sensor

(75) Inventor: Petri Ahonen, Jyvaskyla (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 11/479,555

(22) Filed: Jun. 30, 2006

(51) Int. Cl. H03K 17/94; H04N 9/73; H04N 5/225

(52) U.S. Cl. 348/223.1; 348/376; 341/20; 348/E09.002

(57) ABSTRACT

A mobile electronic device with an image sensor and a shutter key. The shutter key includes a touch sensor and a resilient switch. A processor in the device is configured to activate an automatic camera function, such as an autofocus function when a user touches the touch sensor. The processor is also configured to photograph a subject when the user presses the shutter key and thereby activates the resilient switch.

### FIELD OF THE INVENTION

The present invention relates to mobile electronic devices that are provided with an imaging device, such as a digital camera or the like and more particularly, to an imaging device provided with a shutter key and with an autofocus function that automatically performs focus adjustment of the imaging device.

### BACKGROUND OF THE INVENTION

In recent years digital cameras have been commonly used as imaging devices for photographing subjects. A conventional digital camera (such as a digital still camera or digital video camera) generally acquires an image by using an imaging element such as a CCD or the like, and records the image as digital image data in an internal memory or IC card provided inside the camera or on a recording medium such as a magnetic tape or the like. In an imaging device such as the above-described digital camera, a lens is provided for the purpose of focusing a subject image onto the imaging element when a subject is being photographed. By controlling focusing of the lens, a focusing distance can be aligned with the subject. Consequently, imaging devices provided with autofocus functions for automatically aligning focusing distances with subjects have been conventionally suggested. The autofocus function is activated when a shutter key of the digital camera is half-pressed. At this time, a focusing lens is moved to position in which the present subject is in focus. Moreover, other automatic camera functions can be activated when the shutter switch is half depressed, such as B/W balance, and light exposure via aperture size and shutter speed.

When the shutter key of the digital camera is fully depressed, the digital camera photographs a subject and the photographed image data is stored into a main storage device of the digital camera.

Two-stage shutter keys have a relatively complicated mechanical structure which negatively influences the reliability, form factor and placement in the electronic device. Further, it is difficult to obtain the correct feel and accuracy in a two-stage shutter button that is both reliable and inexpensive enough for mass-produced electronic devices.

### DISCLOSURE OF THE INVENTION

On this background, it is an object of the present invention to provide a mobile electronic device with a digital camera and a shutter key functionality that overcomes or at least reduces the problem described above.

This object is achieved by providing a mobile electronic device, the device comprising a processor controlling the operation of the device, a digital camera coupled to the processor, a key coupled to the processor, the key comprising a touch sensor and a resilient switch, and the processor being configured to activate an automatic camera function when the touch sensor is touched, and the processor being configured to photograph a subject when the resilient switch is depressed.

Thus, a reliable and inexpensive shutter key functionality for a digital camera in a mobile electronic device is obtained. Touch sensors are relatively inexpensive and reliable. Resilient switches with only one stage are also inexpensive and reliable. When these two components are combined an inexpensive and reliable two-stage shutter key is obtained.

The automatic camera function may comprise an autofocus function and/or an automatic light exposure function and/or an automatic B/W balance function.

The touch sensor can be part of an elongated touch sensitive surface. In this case, the processor unit can be configured to change the zoom settings of the digital camera in response to a sliding movement registered by the elongated touch sensitive surface. Thus, an inexpensive and reliable combined shutter key and zoom key are obtained.

Preferably, the resilient switch is a dome switch, which is inexpensive and reliable as well as proven in the field.

The key that is used as shutter key can be a multifunctional key, such as a navigation key or a navigation plus select key.

The object above is also achieved by providing a shutter key for a digital photo camera, the shutter key comprising a resilient switch and a touch sensor, the touch sensor being disposed such that the touch sensor will be touched by a user before and during depression of the switch by a user.

Preferably, the resilient switch is a dome switch.

The touch sensor can be disposed on the movable part of the shutter key. In this case, the touch sensor is connected to a static part of the shutter key via a flexible film

The sensor can be part of an elongated touch sensitive surface.

Further objects, features, advantages and properties of the mobile electronic device and shutter key according to the invention will become apparent from the detailed description.

### BRIEF DESCRIPTION OF THE DRAWINGS

In the following detailed portion of the present description, the invention will be explained in more detail with reference to the exemplary embodiments shown in the drawings, in which:

FIG. 1 is a front view of a mobile electronic device according to a first embodiment of the invention,

FIG. 2 is a rear view of the device shown in FIG. 1,

FIG. 3 is a side view of the device shown in FIG. 1,

FIG. 4 is a side view on a shutter key according to a first embodiment of the invention,

FIG. 5 is a side view on a shutter key according to a second embodiment of the invention,

FIG. 6 is a side view on a shutter key according to a third embodiment of the invention,

FIG. 7 is a perspective view of a mobile electronic device according to a second embodiment of the invention, and

FIG. 8 is a block diagram illustrating the general architecture of a mobile phone in accordance with the present invention.

### DETAILED DESCRIPTION OF PREFERRED EMBODIMENTS

In the following detailed description, the mobile electronic device and the shutter key according to the invention in the form of a cellular/mobile phone will be described by the preferred embodiments.

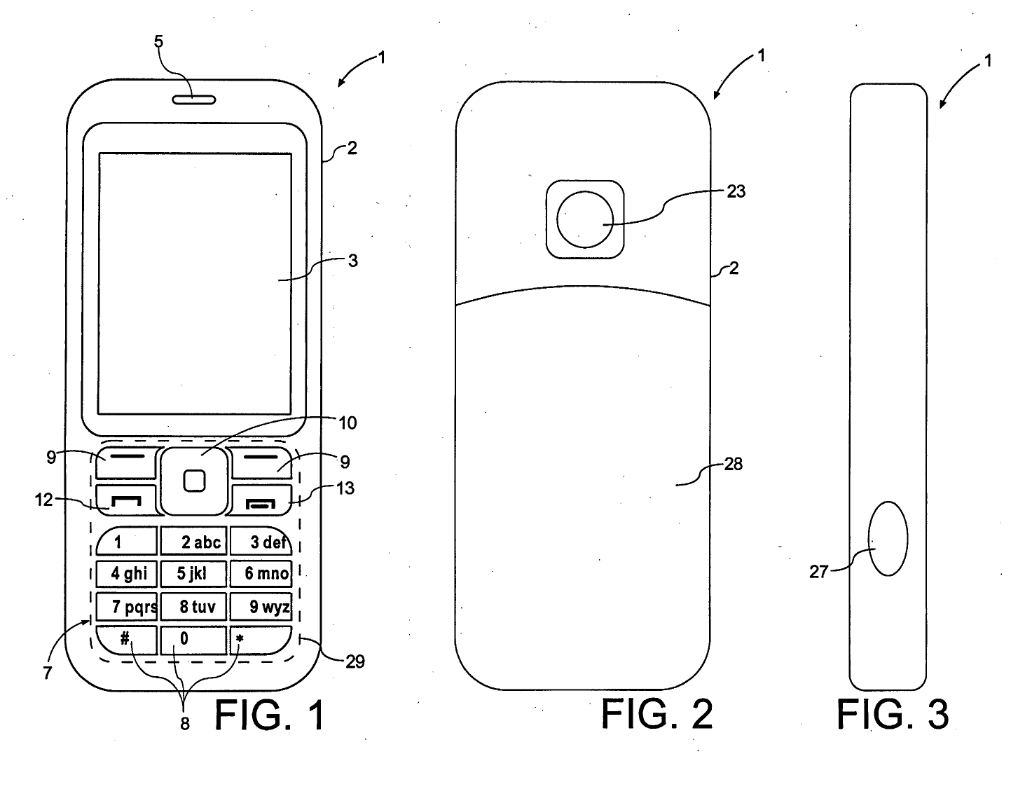

FIGS. 1 to 3 illustrate a first embodiment of a mobile terminal according to the invention in the form of a mobile telephone 1 by a front view and a rear view, respectively. The mobile phone 1 comprises a user interface having a housing 2, a display 3, an on/off button (not shown), a speaker 5 (only the opening is shown), and a microphone 6 (only the opening in the housing 2 leading to the microphone is shown). The phone 1 according to the first preferred embodiment is adapted for communication via a cellular network, such as the GSM 900/1800 MHz network, but could just as well be adapted for use with a Code Division Multiple Access (CDMA) network, a 3G network, or a TCP/IP-based network to cover a possible VoIP-network (e.g. via WLAN, WIMAX or similar) or a mix of VoIP and Cellular such as UMA (Universal Mobile Access).

The keypad 7 has a first group of keys 8 with alphanumeric keys. The keypad 7 has additionally a second group of keys comprising two softkeys 9, two call handling keys (offhook key 12 and onhook key 13), a five way navigation key 10 for scrolling and selecting. The function of the softkeys 9 depends on the state of the mobile phone 1, and navigation in the menu is performed by using the navigation key 10. The present function of the softkeys 9 is shown in separate fields (soft labels) in a dedicated area of the display 3, just above the softkeys 9. The two call handling keys 12,13 are used for establishing a call or a conference call, terminating a call or rejecting an incoming call.

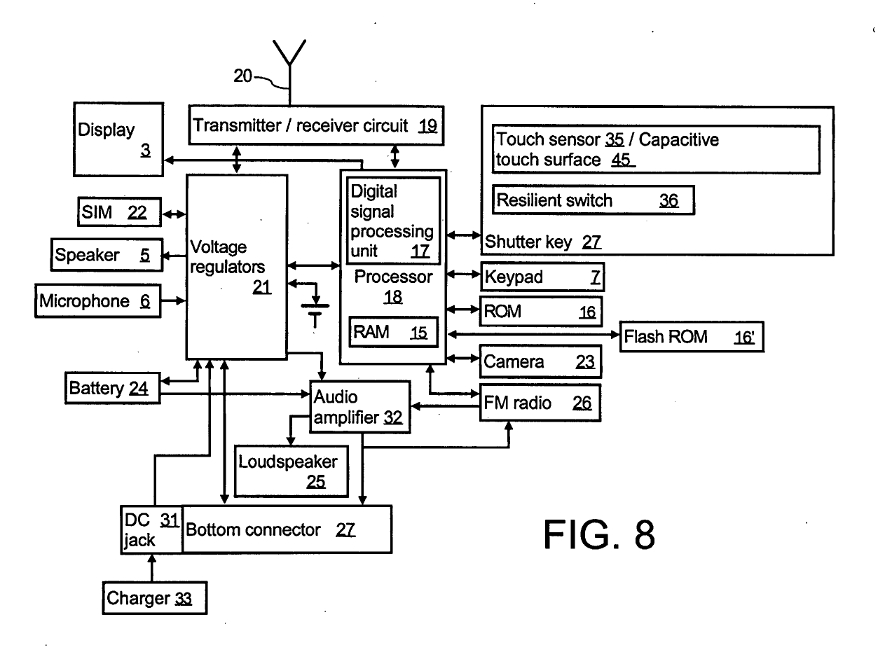

A releasable rear cover 28 gives access to the SIM card 22 (FIG. 8), and the battery pack 24 (FIG. 8) in the back of the mobile phone 1 that supplies electrical power for the electronic components of the mobile phone 1.

The mobile phone 1 has a flat display 3 that is typically made of an LCD with optional back lighting, such as a TFT matrix capable of displaying color images.

A digital camera 23 (only the lens is visible in FIG. 2) is placed in the rear side of the mobile phone 1.

A shutter key 27 is provided on one of the narrow sides of the housing 2 and positioned user-friendly for taking pictures with the mobile phone 1/display 3 in the “landscape” orientation. The shutter key 27 can be completely flush with the surface of the camera housing 2 in which it is disposed.

Optionally, the navigation key 10 can also be configured as a shutter key. Hereto, the area 29 indicated with the interrupted line is provided as a touch sensitive area. The navigation key 10 includes a resilient switch (not shown) that can be activated by depressing the navigation key 10. The area 29 can include the whole keypad 7, only the navigation keys or only the middle key.

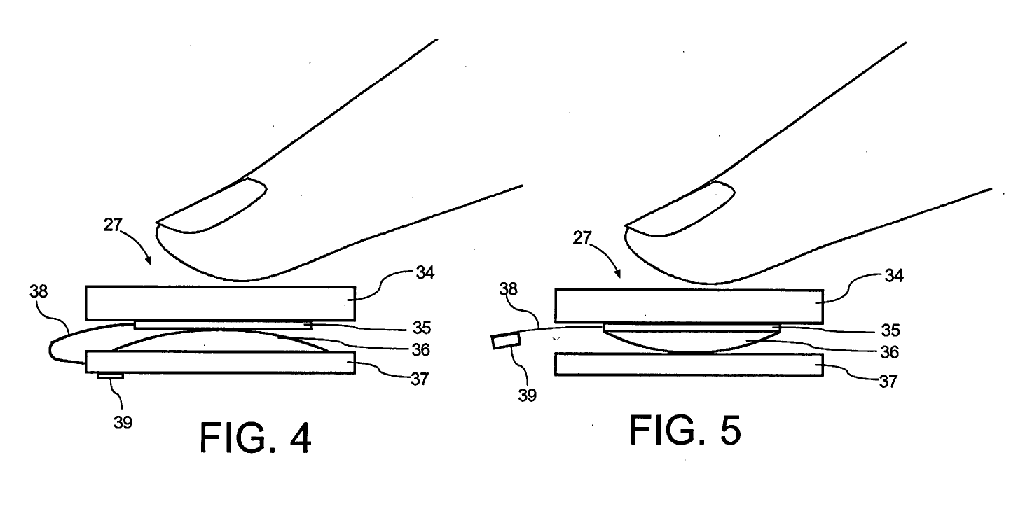

FIG. 4 shows a shutter key 27 according to a first embodiment of the invention. The shutter key 27 includes key material 34, a capacitive touch sensor 35 that is disposed under the key material 34, and a dome switch 36 that is disposed between the capacitive touch sensor 35 and a substrate 37. The base of the dome switch 36 is secured to the substrate 37 with the dome facing the capacitive touch sensor 35. The substrate 37 can be part of the frame (not shown) of the mobile phone or part of a larger printed circuit board (not shown) in the mobile phone. The capacitive touch sensor 35 is connected via a flexible printed film 38 to a touch driver IC 39 that can be placed on the back of the substrate 37 or any other suitable location.

FIG. 5 shows a shutter key 27 according to a second embodiment of the invention. The shutter key 27 according to the second embodiment is essentially the same as the shutter key according to the first embodiment, except that the base of the dome switch 36 is secured to the capacitive touch sensor 35 with the dome facing the substrate 37. Further, the touch driver IC 39 is mounted on the flexible printed film 38.

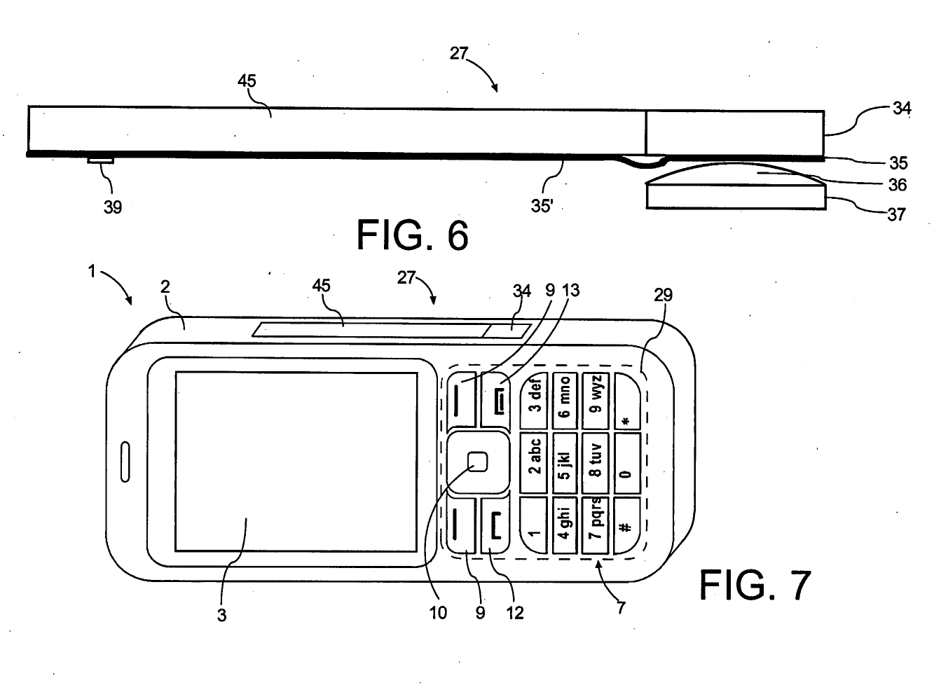

FIG. 6 shows a shutter key 27 according to a third embodiment of the invention. The shutter key according to the third embodiment includes a capacitive touch surface 45 that is placed aside the key material 34. The capacitive touch sensor is formed on a flexible printed film 35′.

FIG. 7 shows a second embodiment of the electronic device according to the invention in the form of a mobile phone 1 that is essentially identical with the mobile phone according to the first embodiment, except that the second embodiment includes the shutter key 27 of the type that is illustrated in FIG. 6.

FIG. 8 illustrates in block diagram form the general architecture of a mobile phone 1 constructed in accordance with the present invention. The processor 18 controls the operation of the terminal and has an integrated digital signal processor 17 and an integrated RAM 15. The processor 18 controls the communication with the cellular network via the transmitter/receiver circuit 19 and an internal antenna 20. A microphone 6 coupled to the processor 18 via voltage regulators 21 transforms the user's speech into analogue signals, the analogue signals formed thereby are A/D converted in an A/D converter (not shown) before the speech is encoded in the DSP 17 that is included in the processor 18. The encoded speech signal is transferred to the processor 18, which e.g. supports the GSM terminal software. The digital signal-processing unit 17 speech-decodes the signal, which is transferred from the processor 18 to the speaker 5 via a D/A converter (not shown).

The voltage regulators 21 form the interface for the speaker 5, the microphone 6, the LED drivers 19 (for the LEDS backlighting the keypad 7 and the display 3), the SIM card 20, battery 24, the bottom connector 27, the DC jack 31 (for connecting to the charger 33) and the audio amplifier 33 that drives the (hands-free) loudspeaker 25.

The processor 18 also forms the interface for some of the peripheral units of the device, including a ROM memory 16, a Flash ROM memory 16, the graphical display 3, the keypad 7, the navigation key 10, the digital camera 23 and an FM radio 26 and the shutter key 27, which includes the touch sensor 35, eventually the capacitive scroll surface 45 and the resilient switch 36. Optionally, the processor 18 is also coupled to the touch sensitive area 29.

The software in the ROM 16 contains instructions for the processor 18 to perform automatic camera functions when the touch sensor 35 is touched by the user. Depending on the type of digital camera 23 that is used in the mobile phone 1, these automatic functions that are started when the touch sensor 35 is touched may include automatic B/W (black and white) balance, light exposure and autofocus. Further, other functions can be initiated when the touch sensor 35 is touched: indications in display (like focus found) and tones from speakers for confirming the activation of the automatic functions. Also a flashlight synchronization function (when flashlight is available) and an autofocus-light that enlightens the item being focused can be automatically activated by the touch sensor 35.

It is not necessary that all of these functions are present, since for example simple digital cameras are single focus and do therefore not need an autofocus function.

In the embodiment where the shutter key 27 includes a capacitive scroll surface 45, the software in the ROM 16 includes instructions for the processor 18 to zoom in on the subject that is to be photographed for one direction of sliding movement that is detected by the capacitive touch surface 45, and instructions for the processor 18 to zoom out from the subject that is to be photographed for the opposite direction of sliding movement that is detected by the capacitive touch the surface 45.

The software in the ROM 16 may further include instructions for the processor 18 to zoom in on a picture shown on the display 3 for one direction of sliding movement that is detected by the capacitive touch surface 45, and instructions for the processor 18 to zoom out from a picture shown on the display 3 for the opposite direction of sliding movement that is detected by the capacitive touch surface 45.

The software in the ROM 16 includes further instructions for the processor 18 to photograph a subject with the electronic camera and to store the photographed image data into the flash ROM 16′ when the resilient switch 36 is depressed.

The software in the ROM 16 may include further instructions for the processor to retrieve image data from the flash ROM 16′ and to display the retrieved image data on the display 3.

In an alternative embodiment, the digital camera 23 has a continuous autofocus function and touching the touch sensor 35 locks the autofocus function.

Although the invention has been described with reference to a mobile phone 1 that is provide with an imaging device, it should be understood that the mobile electronic device according to the invention does not need to be a mobile phone. Instead, it could be a digital camera, a PDA provided with an imaging device, a music or multimedia player provided with an imaging device, etc.

The term “comprising” as used in the claims does not exclude other elements or steps. The term “a” or “an” as used in the claims does not exclude a plurality. The single processor or other unit may fulfill the functions of several means recited in the claims.

Although the present invention has been described in detail for purpose of illustration, it is understood that such detail is solely for that purpose, and variations can be made therein by those skilled in the art without departing from the scope of the invention.

1. A mobile electronic device, said device comprising:
a processor controlling the operation of the device,
a digital camera coupled to the processor,
a key coupled to the processor,
said key comprising a touch sensor and a resilient switch, and
said processor being configured to activate an automatic camera function when the touch sensor is touched, and said processor being configured to photograph a subject when said resilient switch is depressed.

2. An electronic device according to claim 1, wherein said automatic camera function comprises an autofocus function and/or an automatic light exposure function and/or an automatic B/W balance function.

3. An electronic device according to claim 1, wherein said touch sensor is part of an elongated touch sensitive surface.

4. An electronic device according to claim 3, wherein said processor unit is configured to change the zoom settings of said digital camera in response to a sliding movement registered by said elongated touch sensitive surface.

5. An electronic device according to claim 1, wherein said resilient switch is a dome switch.

6. An electronic device according to claim 1, wherein said key is a multipurpose key.

7. An electronic device according to claim 6, wherein said key is a navigation key.

8. An electronic device according to claim 7, wherein said key is a navigation plus select key.

9. A shutter key for a digital photo camera, said shutter key comprising a resilient switch and a touch sensor, said touch sensor being disposed such that the touch sensor will be touched by a user before and during depression of the switch by a user.

10. A shutter key according to claim 9, wherein said resilient switch is a dome switch.

11. A shutter key according to claim 9, wherein said touch sensor is disposed on the movable part of the shutter key.

12. A shutter key according to claim 11, wherein said touch sensor is connected to a static part of the shutter key via a flexible film

13. A shutter key according to claim 11, wherein said touch sensor is part of an elongated touch sensitive surface.
